(19) United States
(12) Patent Application Publication
(10) Pub. No.: US 2023/0392255 A1
(43) Pub. Date: Dec. 7, 2023

(54) Multiple Chamber System for Plasma Chemical Vapor Deposition of Diamond and Related Materials

(71) Applicant: Plasmability, LLC., Austin, TX (US)

(72) Inventor: William Holber, Winchester, MA (US)

(73) Assignee: Plasmability, LLC., Austin, TX (US)

(21) Appl. No.: 18/328,726

(22) Filed: Jun. 3, 2023

Related U.S. Application Data
(60) Provisional application No. 63/349,361, filed on Jun. 6, 2022.

(51) Int. Cl. C23C 16/27; H01J 37/32; C23C 16/505; C23C 16/52; C23C 16/46; C23C 16/458; C23C 16/511

(52) U.S. Cl. CPC C23C 16/272; H01J 37/32201; H01J 37/321; C23C 16/505; C23C 16/52; C23C 16/463; C23C 16/4581; C23C 16/511; C23C 16/274; H01J 2237/3321

(57) ABSTRACT

A plasma chemical vapor deposition system for growing diamond and diamond-like materials includes a process chamber having an exhaust port that is coupled to an input of a vacuum pump. A plasma generator generates a plasma in the process chamber. A cooling stage is positioned in the process chamber with a substrate holder positioned on a top surface that is configured to mount one or more substrates so they are exposed to the plasma generated by the plasma generator. The substrate holder defines a plenum having one or more portions. One or more pressure controllers are each configured to control a pressure in one of the first and second portion of the plenum so as to control a relative temperature of adjacent portions of the substrate holder.

### CROSS-REFERENCE TO RELATED APPLICATION

The present application is a non-provisional application of U.S. Provisional Patent Application No. 63/349,361, filed on Jun. 6, 2022, entitled “Multiple Chamber System for Plasma Chemical Vapor Deposition of Diamond and Related Materials”. The entire disclosure U.S. Provisional Patent Application No. 63/349,361 is incorporated herein by reference.

### INTRODUCTION

The market for synthetic lab-grown diamond is growing rapidly. This is due, at least in part, to the many desirable material properties of diamond, such as excellent hardness, chemical stability, low-thermal expansion, high thermal conductivity, wide electronic bandgap and broad optical transmission. Grown diamond material is currently used in numerous and growing numbers of applications including, for example, abrasives, electronics, optics, experimental physics, and gems. Lab grown diamond technology has been steadily advancing for the last several decades. The technology has now been widely commercialized and represents a growing portion of the market compared with naturally occurring diamond. One market that has been very rapidly growing is the jewelry market because the optical quality of lab-grown diamond is now so good that it even compares to naturally occurring diamond.

### BRIEF DESCRIPTION OF THE DRAWINGS

The present teaching, in accordance with preferred and exemplary embodiments, together with further advantages thereof, is more particularly described in the following detailed description, taken in conjunction with the accompanying drawings. The person skilled in the art will understand that the drawings, described below, are for illustration purposes only. The drawings are not necessarily to scale; emphasis instead generally being placed upon illustrating principles of the teaching. The drawings are not intended to limit the scope of the Applicants' teaching in any way.

FIG. 1 illustrates a plasma chemical vapor deposition system for growth of

diamond material with substrate temperature control according to the present teaching.

FIG. 2 illustrates a plasma chemical vapor deposition system for growth of diamond material with a substrate holder mounted on top of a cooled stage including a first and optionally a second pressure controller configured to separately control the pressure in volume between the substrate holder and the cooled stage (plenum pressure) under different portions of the substrate holder according to the present teaching.

FIG. 3 illustrates a dual-chamber plasma chemical vapor deposition system for growth of diamond material where each of the chambers has a substrate holder mounted on top of a cooled stage.

FIG. 4 illustrates a plasma chemical vapor deposition system for growth of diamond material with a substrate holder mounted on top of a cooled stage including a first and optionally a second pressure controller configured as described in connection with FIG. 2 that includes a clamping mechanism to adjust the performance of the gas seal positioned between the substrate holder and the cooling stage and the thermal response of the substrate holder.

### DESCRIPTION OF VARIOUS EMBODIMENTS

The present teaching will now be described in more detail with reference to exemplary embodiments thereof, as shown in the accompanying drawings. While the present teaching is described in conjunction with various embodiments and examples, it is not intended that the present teaching be limited to such embodiments. On the contrary, the present teaching encompasses various alternatives, modifications, and equivalents, as will be appreciated by those of skill in the art. Those of ordinary skill in the art having access to the teaching herein will recognize additional implementations, modifications, and embodiments, as well as other fields of use, which are within the scope of the present disclosure as described herein.

It should be understood that the individual steps of the methods of the present teaching may be performed in any order and/or simultaneously as long as the teaching remains operable. Furthermore, it should be understood that the apparatus and methods of the present teaching can include any number or all of the described embodiments as long as the teaching remains operable.

The present teaching relates to synthetic lab-grown single crystal diamond and related materials and methods of making such diamonds and related materials. Synthetic diamond materials have been produced in laboratories for many years by a variety of means. Lab-grown diamond is the common terminology for diamond material made in a fabrication facility rather than dug out of the ground. There are a few common methods by which lab-grown diamonds are made.

One early method of growing diamond is the High-Pressure High Temperature (HPHT) method that uses a starting piece of diamond, which is typically referred to as a seed. This method exposes the seed to extremely high temperature and pressure in the presence of carbon and certain catalytic material. More specifically, in the HPHT process, diamond seed material is placed in a specially designed press, which will allow the growth region to be heated to approximately 1300-1600 degrees C. at pressures exceeding 800,000 pounds per square inch. A carbon starting material dissolves in a metallic catalyst that forms on the starting seed material.

Another early method of growing diamond is sometimes called the hot filament (HF) method. In the HF process, heated filaments of refractory materials such as tungsten are used to dissociate gas mixtures, which typically comprise hydrogen and a hydrocarbon gas such as methane, so that carbon-containing species can deposit on the starting substrates, resulting in diamond growth.

Beginning in the 1980's, investigators began looking at plasma chemical vapor deposition (CVD) techniques to form synthetic diamond films. The CVD method also uses a substrate that is placed in a vacuum vessel at high temperature in the presence of a plasma discharge formed of hydrogen, carbon-containing gases, and optionally smaller amounts of other gases. The plasma discharge is typically formed using a microwave-based reactor operating in the general pressure range of 10-300 Torr. The temperature of substrate material is typically elevated to a temperature that is in the range of 600-1400 degrees C. The exposure of the substrate material to reactive species in the plasma enables the growth of diamond material on the surface.

The diamond material grown in the plasma chemical vapor deposition system may be single crystal diamond, polycrystalline diamond, nanocrystalline diamond, diamond-like carbon or combinations of such materials. The process conditions (e.g., including gas pressure and composition, gas flow rate, substrate temperature) along with the nature of the growth substrate (e.g., single crystal diamond or other material) will determine the type of material that is grown. Applications are wide-ranging and including cutting tools, gems, optics, windows, orifices, electronic materials, sensors, heatsinks, detectors, wear coatings and many other. Other carbon-based materials such as graphene and carbon nanotubes may also be grown in the system.

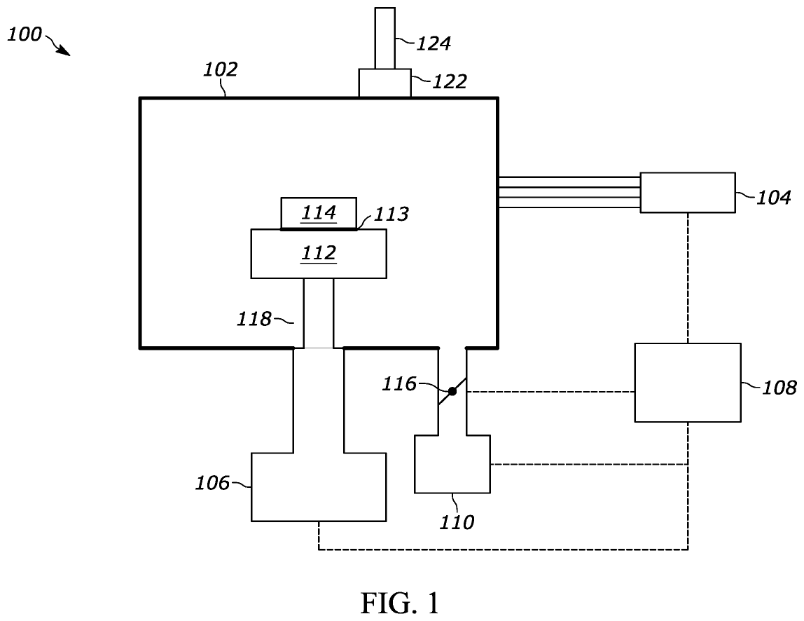

FIG. 1 illustrates a plasma chemical vapor deposition system 100 for growth of diamond material with substrate temperature control according to the present teaching. The plasma chemical vapor deposition system 100 includes the following functional elements: (1) process chamber 102 and its components including a vacuum pump 110; (2) gas delivery system 104; (3) plasma generator 106; and (4) computer and control electronics 108 that allows the various functions of the CVD system 100 to be controlled and automated and data to be analyzed and stored.

The process chamber 102 is a vacuum chamber that is coupled to a vacuum pump 110. The vacuum pump 110 is a mechanical device that pumps the gases out of the vacuum system. The process chamber 102 includes a cooled stage 112 on which seed material, or a substrate holder 114 for supporting the seed material, is positioned. In one particular configuration, the cooled stage 112 is cooled by circulating water or other fluid. In some configurations, an intermediate spacing element 113 between the substrate holder 114 and the cooled stage 112 is used, which can be constructed of any of the following: molybdenum; tungsten or another refractory metal; a high-temperature ceramic; a high-temperature carbon-containing material; a high-temperature semiconductor material such as silicon; or any other material able to withstand the temperature of the substrate holder and the chemistry of the gaseous species. Spacing element 113 can be used to control the heat transfer between the substrate holder 114 and the cooled stage 112. The spacing element 113 may also be placed between the growth sample and the substrate holder 114 in order to control the thermal transfer between those two elements.

The growth samples are placed on the substrate holder 114. Alternatively, the growth samples can be placed directly on the cooled stage 112. Substrate holders 114 constructed of molybdenum, tungsten or other refractory metals are often used. Other materials, such as aluminum oxide, aluminum nitride, silicon carbide, numerous types of ceramics, and silicon, can also be used. Metals such as copper and stainless steel can be used for some applications. Polycrystalline diamond substrate holders may also be used. For some applications, the geometry of the substrate holder 114 is optimized for temperature uniformity to match the plasma discharge shape, thermal characteristics and chemistry. See, for example, U.S. patent application Ser. No. 17/424,081, entitled “Method of Growing Single Crystal Diamond Assisted by Polycrystalline Diamond Growth”.

The gas delivery system 104 allows the various process gases to be introduced into the process chamber and typically includes a set of mass flow controllers, each of which precisely controls the flow of one or more specific gases. A vacuum throttle or butterfly valve 116, which is positioned between the process chamber 102 and the vacuum pump 110, can be used for controlling chamber pressure. A vacuum isolation valve (not shown) can also be positioned between the vacuum throttle valve 116 and the vacuum pump 110. This isolation valve is a valve that when closed isolates the process chamber 102 from the vacuum pump 110.

The vacuum throttle valve 116 is often used to control the pressure in the process chamber 102 independently of the mass flow controller settings in the gas delivery system 104. This allows for very precise control of conditions in the process chamber 102. However, it should be understood that vacuum throttle valves, such as valve 116, are not necessary to practice some embodiments of the present teaching. In some cases, the operation of the vacuum pump 110 can be controlled so that the pump speed can be varied, allowing management of the chamber pressure.

The plasma generator 106 include a power supply such as a microwave power supply that typically operates at 2.45 GHz or 915 MHz or a radio-frequency system that typically operates at 20 kHz to greater than 14 MHz, but can also be a direct-current system. Typically, systems use microwave power supplies operating at either 2.45 GHz or at 915 MHz in frequency, and at power levels as low as 1 kW to greater than 100 kW. Operating at microwave frequencies is attractive because the energy travels in a wave and the geometry of the process chamber is configured to allow the discharge to be centered near the substrate where the deposition occurs, and away from the process chamber walls. This feature of operating at microwave frequencies improves efficiency and also reduces contamination. Other RF and microwave frequencies can be used. However, some of the frequencies detailed herein are the most commonly used frequencies as they are reserved for industrial applications by international agreement. Consequently, there is good availability of relatively inexpensive components.

More recently, other frequencies for the power supplies for the plasma generator 106 and other techniques for coupling the power to the plasma discharge have been developed that are suitable for CVD diamond growth. One such technique is a toroidal plasma discharge in which RF power at 400 kHz is inductively coupled through a transformer structure into a closed-loop discharge. See, for example, U.S. Pat. No. 10,443,150, entitled “Toroidal Plasma Processing Apparatus with a Shaped Workpiece Holder”, and U.S. Patent No. 9,909,215, entitled “Toroidal Plasma Processing Apparatus”, which are both assigned to the present assignee. Other RF frequencies may be utilized in the toroidal discharge as well, from as low as 20 kHz to over 14 MHz. Another example is that of using a direct current (DC) discharge as the plasma generator in a CVD diamond system.

The plasma chemistry for depositing diamond by CVD includes mainly hydrogen chemistry with the addition of a small amount of a carbon-containing gas, such as methane or acetylene. Gases, such as oxygen and argon, may also be utilized. Gases containing one or more dopant material, such as boron, can also be added in combination with other gases. The plasma dissociates some fraction of the hydrogen as well as the carbon-containing species. Atomic hydrogen adsorbs onto the growing diamond surface and also preferentially etches away non-diamond carbon-bonds in favor of diamond bonds. The plasma in the process chamber generates the appropriate chemistry to promote the growth of either single-crystal diamond or polycrystalline diamond material, depending on the growth substrate chosen and the process conditions.

In order to achieve relatively high rate growth of diamond, it is necessary for the plasma discharge to be of sufficient intensity such that the gas in the core of the discharge is heated to greater than 2,000 degrees C. The high gas temperature is necessary in order to maintain a high degree of dissociation of the hydrogen gas into atomic hydrogen, which is critical to the growth of high-quality material at high rates needed for commercial applications. The conditions that will generate these high gas temperatures are typically total gas pressure greater than 20 Torr and power delivered into the plasma core at a density of greater than 50 W cm⁻³. To achieve the highest rates, power delivered into the plasma core may exceed 100 W cm⁻³ and pressures may exceed 100 Torr, resulting in a gas temperature in the plasma core that may exceed 3000 C. In some cases, lower power densities into the plasma and lower pressures may give adequate process results and processing times for commercial applications.

One feature of the present teaching is the understanding that the various components and subsystems comprising the CVD processing system can be configured in several different ways to provide certain performance advantages. Most systems in use today are configured with the process chamber mounted in a frame separate from the frame containing system components such as the plasma power supply, computer, and AC distribution systems. Interconnect cables connect the process chamber components and the support elements. This adds complexity and cost and also requires additional floor space.

One aspect of the present teaching is the realization that conventional CVD systems used for diamond growth are unnecessarily complex, expensive, and physically large. One feature of the apparatus of the present teaching is that various support elements can be mounted in the same frame as the process chamber 100, which can greatly reduce complexity and cost as well as greatly reduce the physical footprint of the apparatus. For example, the plasma generator 106 can include a microwave power generator, an isolator which protects the generator from reflected power, a tuning element, and waveguide elements conducting the microwave power from the generator into the process chamber can be integrated into the system in a particularly space efficient way.

In one configuration, the cooled stage is isolated from the main chamber body with a dielectric window 118 that is at least partially transparent to microwave energy so that microwave energy can be transmitted into the process chamber 102 to form a plasma.

In some systems, the position of the plasma discharge relative to the samples may be manipulated by mechanically moving the cooled stage 112 assembly during the growth process. Alternatively, a magnetic field may be introduced either from within the process chamber or external to it, so as to move the plasma discharge relative to the samples or to change the shape of the plasma discharge. Moving the position of the plasma relative to the samples or changing the shape of the plasma can be useful for achieving various process goals, such as expanding the process deposition area and improving the uniformity of the deposition area.

In one embodiment of the apparatus of the present teaching, a dielectric window 118 is positioned beneath the cooled stage 112 to allow the introduction of microwave energy into the process chamber 102 as shown in FIG. 1. In other embodiments, the dielectric window is positioned on the side or top of the chamber. The dielectric window 118 is formed of materials that allow the passage of the particular frequency of microwave energy that is used to form the plasma. Examples, of suitable materials include quartz and other glasses, and ceramics, such as aluminum oxide and aluminum nitride.

In another embodiment, multiple cooled stages 112 and substrate holders 114 are used. As an example, a second cooled stage and substrate holder may be located opposite to or at an angle to the cooled stage, allowing more efficient use of the reactants generated in the plasma discharge and thereby increasing the output of the growth system.

An important parameter for growing CVD diamond material is temperature control of the growing material. As the material grows, it is often necessary to make adjustments so that a desired temperature is maintained on the growing surface. The temperature of the growing material can be monitored and controlled in several different ways.

Non-contact temperature measurement can be accomplished by using an optical pyrometer or an infrared camera. A single or multiple wavelength pyrometer can be used in combination with an optical galvanometer, allowing temperature measurement across a larger area. Taking temperature measurements by scanning across the substrate holder can be used to create a thermal map of the substrate holder and substrates placed on it. Such a thermal map can be useful for both research and development and for production process temperature measurement and process control.

The process chamber 102 is typically equipped with at least one viewport 122 that has transmission allowing for use of such optical pyrometers and/or cameras 124 and other optical diagnostics instruments. The choice of material used to form the viewport 122 is important so that the viewport 122 allows transmission at the operating wavelength of the instrument. For diagnostic instruments operating at wavelengths between approximately 0.2 microns and approximately 5 microns in wavelength, materials such as quartz, fused silica, various silica glasses, sapphire, calcium fluoride, magnesium fluoride, zinc selenide, zinc sulfide and other glasses can be used. Materials such as silicon and germanium may also be used. For diagnostic instruments 124 operating at wavelengths longer than about 5 microns, materials such as calcium fluoride, magnesium fluoride, zinc selenide and zinc sulfide can be used, along with materials such as silicon and germanium. Consideration also must be given to the robustness of the vacuum window in the viewport 122 with respect to the heat and chemistry it may experience in the process chamber 100. Materials such as silicon and germanium can be used in some embodiments where transmission in the infrared region is required. In some configurations, the dielectric window 118 and/or optical window of viewport 122 are coated with a thin optical film on sides exposed to the plasma or exposed to the ambient environment in order to improve its chemical resistance and/or to optimize the optical characteristics of the window.

Optical pyrometers and/or cameras can be part of diagnostic equipment 124 coupled to the viewport 122 are used to measure sample temperature and temperature changes. In some systems, the operating wavelengths used may be chosen to lie outside of spectral regions where there will be significant interference from the plasma light emission. However, this is not always necessary. In embodiments including an optical pyrometer as diagnostic equipment 124, the pyrometer measures at a single point, and can operate with one or several wavelengths. When multiple wavelengths are used for monitoring, the calculated temperature can be adjusted for changes in the optical emissivity of the growing sample and for changes in the transmission of the optical window of viewport 122.

Infrared cameras as diagnostic equipment 124 have the advantage over optical pyrometers of being able to measure temperature across a wider area. Infrared cameras typically operate at a single wavelength or wavelength band but can operate at multiple wavelengths for improved performance. However, infrared cameras typically do not adjust for changes in optical emissivity of the sample. Using both an infrared camera and an optical pyrometer as diagnostic equipment 124 has some advantages. For example, by using the pyrometer at a single point along with the infrared camera for area measurement, temperature measurement across the larger area can be adjusted for changing optical emissivity.

The substrate holder 114 typically utilizes a temperature control system. In some systems, the substrate holder 114 is formed in a disk-shaped plate that includes elements that provides shielding of the samples from the plasma discharge, while allowing the sample to be at the desired temperature and position relative to the reactive gas species reaching the sample surface.

The temperature of the substrate holder 114 can also be measured directly through the use of thermocouples or other sensors that require direct coupling of the sensor to the object being measured. By measuring the temperature of the substrate holder 114, the temperature of the growing sample can be determined after characterization of the temperature difference between the growing sample and the substrate holder. The temperature of the substrate holder 114 can also be measured through the use of a pyrometer or thermal camera, either from the backside, shielded from the plasma, or from the front side, which is the growing surface.

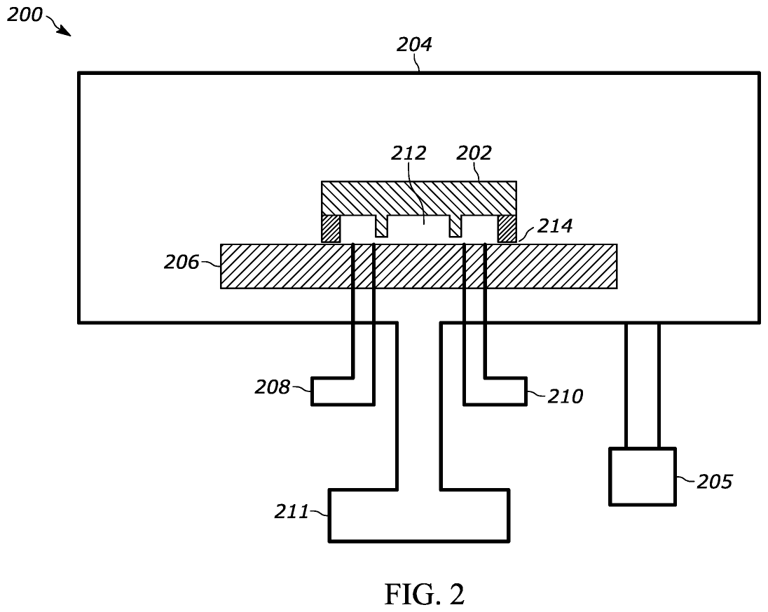

The temperature of the growing material or the substrate holder 114 may be controlled through several different means. Changing process parameters such as chamber pressure, plasma power and process conditions can impact the sample or substrate holder temperature. However, these process parameters may also impact the growth process, particularly if they are changed by a significant amount. A more process independent means of controlling the temperature of the growing material or the substrate holder 114 is often useful. In one embodiment of the present teaching, temperature of the growing material or the substrate holder 114 is changed by changing the thermal contact between the substrate holder and the cooled stage as described further in connection with FIG. 2.

FIG. 2 illustrates a plasma chemical vapor deposition system 200 for growth of diamond material with a substrate holder 202 configured to control the plenum pressure under one or more portions of the substrate holder 202 according to the present teaching. The term “plenum” is defined herein to be the volume between the substrate holder 202 and the cooled stage 206. FIG. 2 schematically shows a process chamber 204 having a port that is coupled to a vacuum pump 205 that evacuates the process chamber 204 to below atmospheric pressure. The substrate holder 202 is configured to mount one or more substrates to be processed. The substrate holder 202 is mounted on top of a cooling stage 206 that controls the temperature of the substrate holder 202 and thus the temperature of the substrate or substrates during processing.

In the configuration shown in FIG. 2, a microwave generator 211 generates and introduces microwave energy into the process chamber 204 through a dielectric window. The dielectric window may be located underneath the cooling stage on the side or top of the chamber or within the microwave waveguide.

A pressure control subsystem allows the gas pressure in the plenum region 212 to be changed separately across the substrate holder 202, allowing for adjusting the temperature uniformity as well as the absolute temperature. In various embodiments, a second or third pressure control system can be used to provide even finer control over the temperature across the substrate holder 202 and thus across the substrate during processing. It should be understood, that the present teachings are not limited to the number of pressure control subsystems that can be used. That is, only one or any number of pressure control subsystems can be used.

A first 208 and optional second pressure controller 210 are configured to separately control a pressure of the plenum 212 under different portions of the substrate holder 202. In various embodiments, depending on the configuration and construction of the substrate holder 202, all or portions or none of the substrate holder 202 can be in physical contact with the cooling stage 206. In one configuration, there is a single plenum region between the cooling stage and the substrate holder for which the pressure is controlled using a single pressure controller. In other configurations, separate plenum regions have the pressure controlled using a single pressure controller instead of multiple controllers. In yet other configurations, there are more than two plenum regions whose pressure is controlled with a single or multiple pressure controllers that can operate in combination with restrictive orifices. The gas lines from the pressure controllers 208 and 210 can be located in various positions so as to not interfere with the microwave energy entering the process chamber 204. The gas lines can be formed of metal or dielectric material, depending on the location and exposure to microwave energy.

One feature of configurations of the present teaching is that the gas in the plenum 212 region, which is gas in the volume between the cooled stage 206 and the back of the substrate holder 202, will efficiently transfer heat from the back of the substrate holder 202 to the surface of the cooling stage 206. A higher plenum gas pressure will increase the rate of heat transfer. Heat transfer is improved when the spacing between the back of the substrate holder 202 and the cooling stage 206 is reduced. Increasing the portion of the substrate holder 202 that is in mechanical or close contact with the cooling stage 206 will also increase the heat transfer.

Known CVD diamond processing systems use a single pressure control subsystem to vary the pressure of the gas in the plenum region 212 between the cooling stage 206 and the substrate holder 202. Such single pressure control systems generally allow adjustment of the temperature of the substrate holder 202 in its entirety. That is, the temperature adjustment is only a single adjustment for the entire substrate holder 202 and will not practically allow for accurate correction of temperature non-uniformity of the substrate holder. That is, the temperature across the substrate holder 202 and thus the substrate cannot be accurately controlled during processing.

Some configurations of CVD diamond growth systems according to the present teaching include a closed loop temperature control system that is under computer control. The closed-loop temperature control system includes a temperature measurement system that can include one or more temperature sensors that measure the temperature of the substrate holder 202 or samples mounted on to substrate holder 202 as a function of position across its surface. A computer includes an input that receives measurement signals from the temperature control system. The computer processes the measurement control signals and provides output control signals to one or more of the pressure controllers that instruct the pressure controllers to change the pressure at various locations in the plenum so as to control the temperature across the surface of the substrate holder 202. Such a temperature control system is advantageous because it can be used to control both the absolute temperature and the temperature uniformity of the substrate holder 202 throughout the growth process. This feature is particularly advantageous for applications requiring larger growth areas, where temperature uniformity is harder to set and maintain. For example, for growth areas having a diameter greater than about five centimeters, a dual or multiple zone pressure control subsystem that controls temperature uniformity would be particularly advantageous.

In some embodiments of the present teaching, a full or partial length gas seal 214 is positioned between the substrate holder 202 and the cooling stage 206. In various embodiments and methods of operation, different types of gas seals 214 can be used. The gas seal 214 may be chosen to compress or deform from the mass of the substrate holder 202 plus the pressure difference between the chamber pressure and the plenum pressure. The gas seal 214 may also be made to compress or deform with a clamping mechanism.

It should be understood that uniformity of the substrate holder 202 temperature can be changed due to flexing of the substrate holder. Temperature uniformity can also be changed by design of the structure of the backside of the substrate holder 202. For example, elements of the backside of the substrate holder 202 that are closer to the cooling stage 206 will have a stronger response to a change in the gap between the backside of the substrate holder 202 and the cooling stage 206 than elements which are further away. The clamping of the substrate holder 202, not shown in FIG. 2, can be accomplished in numerous different ways. Examples include bolts, clamps, and a rod or wire element pulling down from the backside of the substrate holder. Any type of clamping means known in the art can be used.

It is desirable in some configurations of the CVD system 200 according to the present teaching to control gas leakage in at least some regions between the substrate holder 202 and cooling stage 206. Changes in gas leakage between the substrate holder 202 and cooling stage 206 impact the temperature of the substrate holder 202.

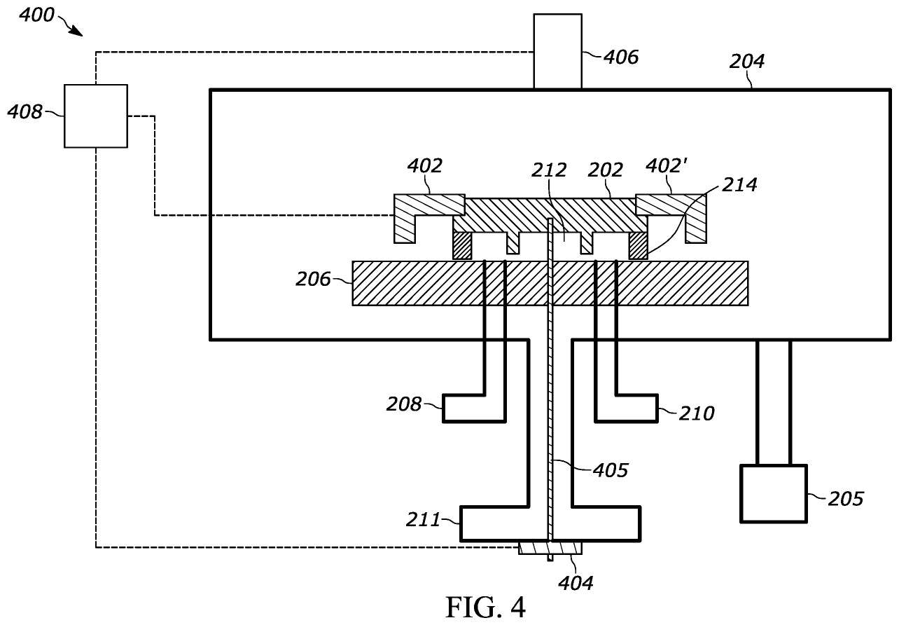

The gas seal 214 can be designed for minimum gas leakage or can be designed for a specific degree of gas leakage in specific areas. In some configurations according to the present teaching, the gas seal 214 is compressible or deformable. In some configurations according to the present teaching, the gas seal 214 is not compressible or deformable. The force needed to compress or deform the gas seal 214 may come from any combination of the mass of the substrate holder 202, gas pressure difference between the process chamber 204 and plenum 212, and/or mechanical means such as clamps and / or bolts as described in more detail in connection with FIG. 4.

When a mechanical means is used to keep the substrate holder 202 in place on the gas seal 214, the pressure in the plenum 212 region may be set to a value higher than that of the process chamber 204. This would have the advantage of increasing the range of operation of the temperature control system.

The selection of the material used to form the gas seal 214 needs to be carefully chosen to be compatible with the process temperatures, process chemistries, and materials grown. For example, the gas seal 214 can be formed of metal, ceramic, or elastomeric material. The gas seal 214 may be formed from a high temperature grease. The gas seal 214 may be formed from an adhesive material. In various embodiments, gas seal 214 is constructed of a combination of different materials to have desired mechanical and chemical resistant properties. In one specific embodiment, the gas seal 214 is formed with a metallic core having a compressible material surrounding it. Examples of materials that can be used for the gas seal include those containing various metals, silicone, carbon, silicon, molybdenum and sulfur.

Another feature of the gas seal 214 between the substrate holder 202 and cooling stage 206 is that it may define the thickness of the gap between the two, which is one factor that defines the substrate holder 202 temperature. Gas seals 214 that are configured to have larger gaps decrease the thermal transfer between the two elements. Gas seals 214 that are configured to have smaller gaps increase the thermal transfer between the two elements. The gas seal 214 can be specifically configured to improve the temperature uniformity of the substrate holder 202.

Another feature of the gas seal between the substrate holder 202 and the cooling stage 206 is that it provides a defined electrical connection between the substrate holder 202 and the cooling stage 206. This can range from highly insulating to highly conductive, or anything in between. This can impact the interaction of the plasma with the substrate holder 202, allowing improvement in uniformity or process rates.

A vacuum throttle valve for mechanically controlling chamber pressure can be used as described in connection with FIG. 1. Such a vacuum throttle valve can be used to control the pressure in the process chamber 204 independently of the mass flow controller settings in order to set the rate at which the various gases flow into the process chamber 204 for a particular operating pressure. Such a configuration more accurately controls reactions rates for particular operating pressures.

One or a plurality of vacuum exhaust ports can be placed around the process chamber 204 to optimize the gas flow, plasma geometry and plasma shape. When used in conjunction with one or more vacuum valves or vacuum throttle valves, the vacuum exhaust ports can be sequenced to allow dynamic changes in the gas flow, plasma geometry and plasma shape. This can be useful, for example, to expand the process deposition area, and/or to allow a greater number of substrates to be processed at one time. By varying the position and geometry of the vacuum exhaust ports in the process chamber, the shape of the plasma discharge can be optimized in order to achieve more highly uniform deposition across the sample area and to expand the effective sample area. The typical gas pressures and gas flow rates used for the CVD diamond process lend themselves particularly to this configuration.

Another aspect of the apparatus of the present teaching is the combination of two or more process chambers such that one or more of the various subsystems described in connection with FIGS. 1 and 2 are shared between or among the multiple chambers. Such a system allows sharing of process gas delivery systems, temperature measurement and diagnostic systems, vacuum chamber and control systems, power systems, computer and control systems, gas and other safety monitoring systems, and physical supporting structures. Some subsystems, such as microwave power may be operated independently or shared among chambers. Such a system is desirable because it can significantly reduce, cost, complexity, and space requirements. In addition, such a system improves reliability.

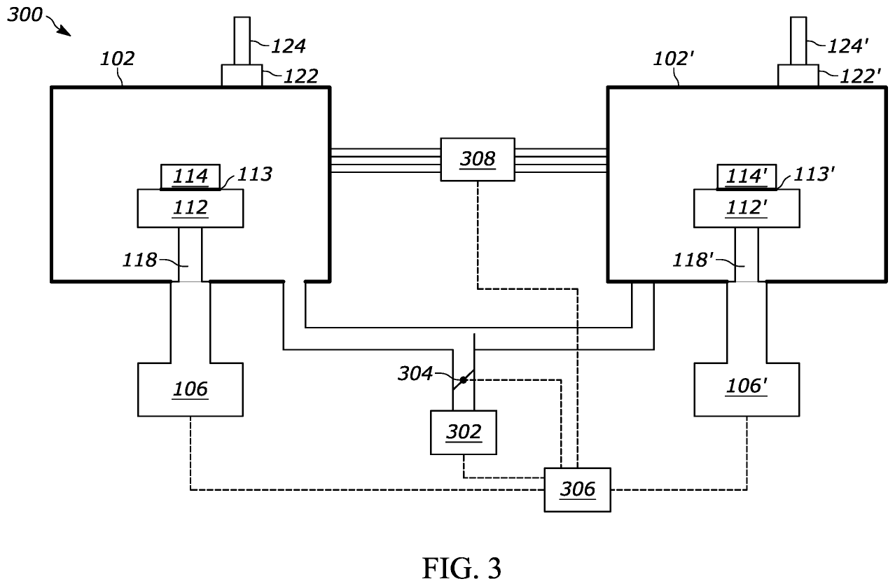

FIG. 3 illustrates a dual-chamber plasma chemical vapor deposition system 300 for growth of diamond material where each of the chambers 102, 102′ has a substrate holder 114, 114′ mounted on top of a cooled stage 112, 112′. More specifically, the dual-chamber plasma chemical vapor deposition system 300 includes a first and second process chamber 102, 102′.

Also as described in connection with FIG. 1, the cooled stages 112, 112′ are cooled by circulating water or other fluid. In some configurations, intermediate spacing elements 113, 113′ are positioned between the substrate holders 114, 114′ and the cooled stages 112, 112′, which can be constructed of any of the following: molybdenum; tungsten or another refractory metal; a high-temperature ceramic; a high-temperature carbon-containing material; a high-temperature semiconductor material such as silicon; or any other material able to withstand the temperature of the substrate holders 114, 114′ and the chemistry of the gaseous species. Spacing elements 113, 113′ can be used to control the heat transfer between the substrate holders 114, 114′ and the cooled stages 112, 112′. The spacing elements 113, 113′ may also be placed between the growth sample and the substrate holders 114, 114′ in order to control the thermal transfer between those two elements.

Also, as described in connection with FIG. 2, growth samples are placed on the substrate holders 114, 114 or alternatively, the growth samples can be placed directly on the cooled stages 112, 112′. Substrate holders 114, 114′ can be constructed of molybdenum, tungsten or other refractory metals are often used. Other materials, such as aluminum oxide, aluminum nitride, silicon carbide, numerous types of ceramics, and silicon, can also be used. Metals such as copper and stainless steel can be used for some applications. Polycrystalline diamond substrate holders may also be used. For some applications, the geometry of the substrate holder is optimized for temperature uniformity to match the plasma discharge shape, thermal characteristics and chemistry.

In the dual-chamber configuration of the plasma chemical vapor deposition system 300 of FIG. 3, there is a common vacuum pumping system that includes a single vacuum pump 302 coupled to an evacuation port of each of the chambers 102, 102′. A vacuum isolation valve (not shown) is sometimes positioned between the vacuum throttle valve 304 and the vacuum pump 302. This vacuum isolation valve is a valve that when closed isolates the process chambers 102, 102′ from the vacuum pump 302.

A throttle valve 304 or butterfly valve controls the conductance between the vacuum pump 302 and the chambers 102, 102′. The throttle valve 304 controls the pressure in the process chambers 102, 102′ independently of the mass flow controller settings. This allows for very precise control of process chamber conditions. In many configurations the throttle value is controlled by a processor, which can be an internal processor that is in communications with a system processor 306. Also, in the dual-chamber configuration, there is a common gas delivery system 308 that provides feed and other gases to both of the chambers 102, 102′. The gas delivery system 308 allows the various process gases to be introduced into the process chamber and typically includes a set of mass flow controllers, each of which precisely controls the flow of one or more specific gases.

As described in connection with FIG. 1, the dual-chamber plasma chemical vapor deposition system 300 includes plasma generator 106, 106′ for plasma generation that can be a microwave power supply that typically operates at 2.45 GHz or 915 MHz or a radio-frequency system that typically operates at 20 kHz to greater than 14 MHz, but can also be direct-current systems. The power generator 106, 106′ can be the same or different. As described in connection with FIG. 1, dielectric windows 118, 118′ can be positioned beneath the cooled stage 112 to allow the introduction of microwave energy into the process chamber 102. In other embodiments, the dielectric window is positioned on the side or top of the chambers 102, 102′.

In various embodiments of the present teaching, the processor 306 controls many aspects of the dual-chamber plasma chemical vapor deposition system 300. In the configuration shown the processor 306 is common in one physical enclosure, however, it should be understood that the processor 306 can be any number of processors that are in electronic communication.

The processor 306 can control the vacuum in the chambers 102, 102′ by controlling the position of the throttle valve 304. Also, the processor 306 controls the gas delivery system 308. Thus, the processor 306 can provide instructions to the dual-chamber plasma chemical vapor deposition system 300 to pump the chambers 102, 102′ down to a base pressure and then to introduce process gases to provide the desired partial pressures of process gases for processing. The processor 306 also controls the power generator 106, 106′ for plasma generation to generate a plasma for plasma chemical vapor deposition. In many configurations according to the present teaching, the processor automates the plasma chemical vapor deposition process in each of the chambers 102, 102′. It should be understood that the processor 306 can control each of the chambers 102, 102′ independently to achieve the same or different process. Thus, the dual-chamber configuration described in FIG. 3 can be configured in many different ways to provide certain performance advantages.

In one specific embodiment, microwave power supplies of the plasma generators 106, 106′, computer and AC power subsystems are positioned above the process chambers 102, 102′ in an overhead structure. This configuration is desirable because it reduces the floor space required for each system, which allows for more efficient factory utilization. Floor space is particularly expensive in fabrication facilities. A configuration with two process chamber system having microwave power supplies of the plasma generators 106, 106′, computer and AC power subsystems are positioned above the process chambers 102, 102′ in an overhead structure can reduce the footprint of the system 300 to be roughly equivalent to the footprint of a typical single chamber microwave system.

In some configurations, all of the support cabling and liquid cooling connecting the microwave power generators to the process chambers 102, 102′ are contained within a closed single structure. This allows a smaller service area around the system than a typical single chamber microwave CVD system.

Also, in some configurations, a dual chamber system is configured in a mirror image layout with the process chambers loading ports opposing another system. This allows the narrower service area of two opposing systems to be placed back-to-back, reducing the required floor space of multiple systems. In this configuration, with multiple systems, an approximate 3:1 floor space requirement per chamber improvement can be achieved compared to traditional single chamber microwave CVD systems.

One feature of embodiments of processing systems that include multiple chambers of the present teaching is that the overall system design is one that enables sharing certain subsystems among at least two and as many process chambers as desired. It is desirable that the gas lines from the gas delivery system to each of the connected chambers be approximately the same length, have approximately the same number and type of bends, and have approximately the same size, in order to maintain equal gas flow among the connected chambers. Alternatively, to having approximately the same length, same number and type of bends, and same size gas lines, flow restrictors can be used at the inlet to each chamber, in order to balance the gas flows. As another alternative, an active balancing device can be used balance the gas flow among each connected chamber.

In some embodiments of processing systems according to the present teaching exhaust lines from each connected chamber are configured to the extent possible to have similar size and configuration between each connected chamber and the throttle valve. This configuration provides similar pumping speed and pumping response time among the connected chambers.

In one embodiment of the present teaching, one or more diagnostic instruments are shared between the various process chambers 102, 102′. One means of measuring sample temperature is to use an optical pyrometer. Known systems generally use a single optical pyrometer for each process chamber. However, it has been determined that it is possible to multiplex multiple sensor heads into a single pyrometer analysis unit. This configuration will save considerable space and cost and will also improve the consistency of the temperature measurements across different process chambers as the same instrument is used, thereby reducing errors due to calibration differences. This could be accomplished, for example, by using optical pyrometers with fiber-based sensors along with a multiplexer that can sequentially feed the signal from individual fiber sensors into a single analysis unit. In one embodiment, an optical galvanometer, which allows an optical signal to be physically scanned, is used to allow a single pyrometer fiber to measure temperature across multiple samples. This can be used both for process monitoring and also for real time multi-zone temperature control. The scanning galvanometer can be used separately from or in conjunction with an optical multiplexer configuration.

Generally, embodiments of plasma chemical vapor deposition diamond deposition systems of the present teaching are well suited to sharing systems and subsystems among multiple process chambers 102, 102′. This is because of the recognition that, in many applications, the growth process takes place over an extended period of time, ranging from hours to many days or weeks. Consequently, slight differences in the start of the growth cycle among the connected chambers is not highly important. This is in comparison to the case for semiconductor processing systems where process times can be as short as minutes or even seconds and slight differences will matter. For a number of CVD diamond growth applications, the absolute thickness of the material grown is not critical, as long as it is in a range that is acceptable. Often a difference of a few percent or more in thickness is not critical.

The diamond CVD growth process typically operates at pressures in the to 500 Torr range, with the dominant gas being hydrogen and other gases which may include or contain oxygen, nitrogen, argon, boron and methane or other carbon-containing gases. Total flow rates of the gases are typically such that the residence time of the gas in the process chamber is quite long, typically ranging from about 1.0 seconds to about 500 seconds. In some applications, the residence time can range between about seconds and 400 seconds. Residence time is determined by the volume of the chamber, the pressure at which the chamber operates, and the flow rate of the gas entering the chamber. For example, with a chamber volume of 5 liters, an operating pressure of 200 Torr and a gas flow rate of 300 sccm, the residence time of gas in the process chamber will be about 250 seconds. In a similar example with a gas flow rate that is 3000 sccm, the residence time of the gas in the process chamber will be about 25 seconds.

On the other hand, if the pressure were just 0.01 Ton, the residence time, for the same chamber volume and flow rate, will be 0.0013 seconds. Under the operating conditions typically used for CVD diamond growth, the residence time of the gas in the process chamber is long, which relaxes the required precision of gas control which might be required for shorter residence times.

FIG. 4 illustrates a plasma chemical vapor deposition system 400 for growth of diamond material with a substrate holder 202 mounted on top of a cooled stage 206 including a first 208 and optionally a second pressure controller 210 configured as described in connection with FIG. 2 that includes clamping mechanism 402, 402′ to adjust the performance of the gas seal 214 positioned between the substrate holder and the cooling stage. The clamping mechanism 402, 402′ can be controlled by a processor 408.

The plasma chemical vapor deposition system 400 is similar to the plasma chemical vapor deposition system 200 that was described in connection with FIG. 2. The system 400 includes a substrate holder 202 configured to control the pressure in a plenum 212 under one or more portions of the substrate holder 202. The process chamber 204 includes a port that is coupled to a vacuum pump 205 that evacuates the process chamber 204. The substrate holder 202 is configured to mount one or more substrates to be processed and is mounted on top of a cooling stage 206 that controls the temperature of the substrate holder 202 and thus the temperature of the substrate or substrates during processing.

The microwave generator 211 generates and introduces microwave energy into the process chamber 204 through a dielectric window. A pressure control subsystem allows the gas pressure in the plenum region to be changed separately across the substrate holder, allowing for adjusting the temperature uniformity as well as the absolute temperature. In various embodiments, a second or third pressure control system can be used to provide even finer control over the temperature across the substrate holder and thus across the substrate during processing. As described in connection with FIG. 2, a first 208 and optional second pressure controller 210 are configured to separately control a pressure of the plenum 212 under different portions of the substrate holder 202.

Also, as described in connection with FIG. 2, a full or partial length gas seal 214 is positioned between the substrate holder 202 and the cooling stage 206. The gas seal 214 can be designed for minimum gas leakage or can be designed for a specific degree of gas leakage in specific areas. In the configuration shown, the gas seal 214 is compressible. In some embodiments, this allows changes in the gas seal 214 caused by the clamping mechanism 402, 402′ in response to control signals from the processor 408.

In the configuration shown in FIG. 4, the gas seal 214 is compressed or deformed by the use of mechanical clamping. The mechanical clamping may be controlled in an adjustable manner, so that the clamping force is adjusted at any point or multiple points during the growth cycle. Adjustments to the clamping can allow the overall temperature of the substrate holder and samples to be changed. For example, a motor 404 can be used to pull a connecting rod 405 or wire in order to flex and/or move the substrate holder. It should be understood that many different types of mechanical mechanisms can be used.

In some embodiment, the mechanical clamping is controlled based on the feedback from a temperature sensor 406. In the configuration shown in FIG. 4, the temperature sensor 406 is used measure the temperature of the substrate holder 202. Numerous types of temperature sensors can be used as described herein. A processor 408 is coupled to both the temperature sensor 406 and to the motor 404 so that the processor can adjust the mechanical tension in response to the temperature of the substrate holder or substrate itself. The processor 408 can also be connected to the clamping mechanism 402, 402′.

### Equivalents

While the Applicants' teaching is described in conjunction with various embodiments, it is not intended that the Applicants' teaching be limited to such embodiments. On the contrary, the Applicants' teaching encompasses various alternatives, modifications, and equivalents, as will be appreciated by those of skill in the art, which may be made therein without departing from the spirit and scope of the teaching.

What is claimed is:

1. A plasma chemical vapor deposition system for the growth of diamond and diamond-like materials, the system comprising:
a) a process chamber having an exhaust port that is configured to be coupled to a vacuum pump that evacuates the process chamber to below atmospheric pressure;
b) a plasma generator coupled to the process chamber, the plasma generator configured to generate a plasma in the process chamber for chemical vapor deposition;
c) a cooling stage positioned in the process chamber;
d) a substrate holder positioned in the process chamber on the cooling stage and configured to mount one or more substrates so they are exposed to the plasma generated by the plasma generator, the substrate holder comprising a plenum having one or more portions;
e) a gas seal positioned between the cooling stage and the substrate holder, the gas seal configured to limit gas flow between the plenum and process chamber; and
f) one or more pressure controllers configured to control a pressure in respective ones of the one or more portions of the plenum, wherein the one or more pressure controllers control the pressure in respective portions of the plenum so as to control a temperature of the substrate holder.

2. The system of claim 1 wherein the gas seal is formed of a compressible or deformable material.

3. The system of claim 1 wherein the gas seal is formed of an incompressible material.

4. The system of claim 1 wherein the gas seal is configured to have a thickness that provides a desired amount of thermal transfer.

5. The system of claim 1 wherein the gas seal is formed with a metallic core.

6. The system of claim 1 wherein the gas seal is a full-length gas seal extending over the entire length between the cooling stage and the substrate holder.

7. The system of claim 1 wherein the gas seal is a partial-length gas seal extending over a portion of a length between the cooling stage and the substrate holder.

8. The system of claim 1 wherein the gas seal is configured to provide a desired amount of gas leakage.

9. The system of claim 1 wherein the gas seal is configured to provide an electrical conductivity that provides a desired interaction of the plasma with the substrate holder.

10. The system of claim 1 wherein the plasma generator comprises a microwave plasma generator.

11. The system of claim 1 wherein the plasma generator comprises an RF plasma generator.

12. The system of claim 1 further comprising a temperature sensor positioned proximate to the substrate holder, the temperature sensor measuring temperature at a surface of the substrate holder and providing feedback to the plenum pressure controller.

13. The system of claim 1 further comprising a temperature sensor that measures temperature at a surface of the substrate holder and that provides feedback to the substrate holder clamping mechanism.

14. The system of claim 1 wherein the plenum comprises two or more portions. The system of claim 1 further comprising a temperature sensor that measures temperature at a surface of one or more samples positioned on the surface of the substrate holder and that provides feedback to the one or more pressure controllers.

16. The system of claim 15 wherein the temperature sensor provides feedback to a substrate holder clamping mechanism.

17. The system of claim 15 further comprising a closed-loop temperature control system having an input that is coupled to the output of the temperature sensor and an output that is coupled to at least one of a first and second pressure controllers, the closed-loop temperature control system controlling pressure in the first and second portion of the plenum so as to achieve a desired temperature profile across portion of the substrate holder.

18. The system of claim 17 wherein the desired temperature profile is a uniform temperature profile.

19. The system of claim 1 wherein a surface of the substrate holder where samples are mounted is greater than five centimeters in length.

20. The system of claim 1 further comprising a throttle valve positioned proximate to the exhaust port in the process chamber, the throttle valve controlling pressure in the process chamber.

21. The system of claim 1 wherein the process chamber comprises a plurality of exhaust ports.

22. The system of claim 1 further comprising a temperature controller that controls a temperature of the substrate holder.

23. The system of claim 1 wherein the substrate holder is formed of a refractory metal.

24. The system of claim 1 wherein further comprising a substrate holder clamping mechanism.

25. A plasma chemical vapor deposition system for the growth of diamond and diamond-like materials, the system comprising:
a) a first process chamber comprising a cooling stage, a substrate holder positioned on a top surface of the cooling stage, a process gas delivery system, a process monitoring system, a control system, and a plasma generator; and
b) a second process chamber comprising a cooling stage, a substrate holder positioned on a top surface of the cooling stage, a process gas delivery system, a process monitoring system, a control system, and a plasma power system,
wherein the first and second process chambers share at least one of their process gas delivery system, process monitoring system, control system, or plasma power system.

26. The system of claim 25 wherein the first and second process chambers are configured in a mirror image layout.

27. The system of claim 25 wherein each of the first and second process chambers further comprise a substrate loading port, the substrate loading ports being positioned opposite one another.

28. The system of claim 25 wherein the plasma power system comprises a microwave power system.

29. The system of claim 25 wherein the plasma power system comprises an RF power system.

30. The system of claim 25 further comprising a diagnostic system that is shared between the first and second process chamber.

31. The system of claim 25 further comprising a gas delivery system that is shared between the first and second process chamber.

32. The system of claim 25 wherein the first and second process chamber share a common vacuum pump.

33. The system of claim 25 wherein the first and second process chamber share a common pressure control system.
